(19) United States
(12) Patent Application Publication
(10) Pub. No.: US 2015/0171278 A1
(43) Pub. Date: Jun. 18, 2015

(54) LED WITH LIGHT DIFFUSION LAYER

(71) Applicant: HON HAI PRECISION INDUSTRY CO., LTD., New Taipei (TW)

(72) Inventors: CHAU-JIN HU, Tu-Cheng (TW); FENG-YUEN DAI, Tu-Cheng (TW); PO-CHOU CHEN, Tu-Cheng (TW)

(73) Assignee: HON HAI PRECISION INDUSTRY CO., LTD., New Taipei (TW)

(21) Appl. No.: 14/108,245

(22) Filed: Dec. 16, 2013

(30) Foreign Application Priority Data
Dec. 12, 2013 (TW) 102145988

(51) Int. Cl. H01L 33/46; H01L 33/52

(52) U.S. Cl. CPC H01L 33/46; H01L 33/52

(57) ABSTRACT

An LED includes a base, a chip mounted on the base, an encapsulant sealing the chip, phosphors doped within the encapsulant and a light diffusion layer covering the encapsulant. The light diffusion layer includes a transparent layer contacting the encapsulant and a plurality of transparent particulates doped within the transparent layer. The transparent particulates have a light refractive index less than that of the transparent layer.

### BACKGROUND

1. Technical Field

The disclosure generally relates to LEDs (light emitting diodes), and more particularly, to an LED having a light diffusion layer.

2. Description of Related Art

Nowadays LEDs (light emitting diodes) are applied widely in various applications for illumination. A typical LED often includes a light emitting chip and an encapsulant sealing the chip. Phosphors may be doped within the encapsulant for changing color of the light emitted from the chip. However, the light passes through the encapsulant in different pathways which have different lengths. Thus, the conversion proportion of the light by the phosphors in the different pathways is also different, resulting in color aberration of the resultant light output from the encapsulant.

What is needed, therefore, is an LED with a light diffusion layer which can address the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the various views.

FIG. 1 shows an LED in accordance with an embodiment of the present disclosure.

FIG. 2 shows an LED in accordance with another embodiment of the present disclosure.

FIG. 3 is similar to FIG. 1, wherein a part of a light diffusion layer of the LED is removed, for showing light pathways with the light diffusion layer, compared with, light pathways without the light diffusion layer.

### DETAILED DESCRIPTION

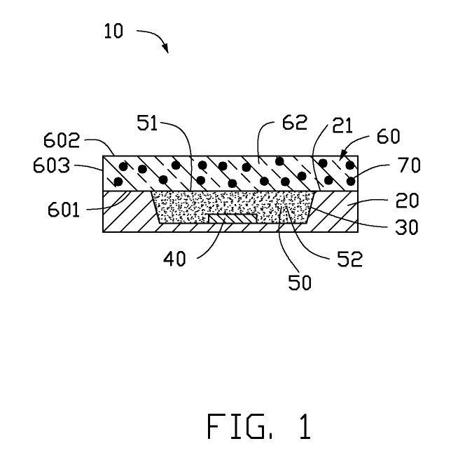

Referring to FIG. 1, an LED (light emitting diode) 10 in accordance with an embodiment of the present disclosure is shown. The LED 10 includes a base 20, a chip 40 mounted on the base 20, an encapsulant 50 sealing the chip 40 and a light diffusion layer 60 covering the encapsulant 50.

The base 20 may be made of a single monolithic piece of insulative material, such as epoxy, silicone or ceramics. The base 20 defines a cavity 30 in a top face 21 thereof. The cavity 30 has a diameter gradually increasing towards the top face 21 of the base 20. An inner circumferential face of the cavity 30 acts as a light reflective face for reflecting light emitted from the chip 40 upwardly. Leads may be formed on the base 20 for electrically connecting the chip 40.

The chip 40 is received in the cavity 30 and surrounded by the light reflective face. The chip 40 may be made of GaN, InGaN, AlInGaN or other suitable semiconductor materials. The chip 40 can emit light when being powered. In this embodiment, the chip 40 emits blue light.

The encapsulant 50 may be made of transparent material such as epoxy, silicone, glass or the like. The encapsulant 50 is filled in the cavity 30 to seal the chip 40 from an outside environment. The encapsulant 50 has a top face 51 flush with that of the base 20.

The encapsulant 50 has a refractive index about 1.6. The encapsulant 50 has a large amount of phosphors 52 doped therein. The phosphors 52 may be made of YAG (yttrium aluminum garnet), silicate, nitrogen oxide or the like. The phosphors 50 can be excited by the light emitted from the chip 40, thereby emitting light having a color different from that of the light directly emitted from the chip 40. In this embodiment, the phosphors 52 emit yellow light when being excited by the blue light of the chip 40, thereby mixing with the blue light to form white light.

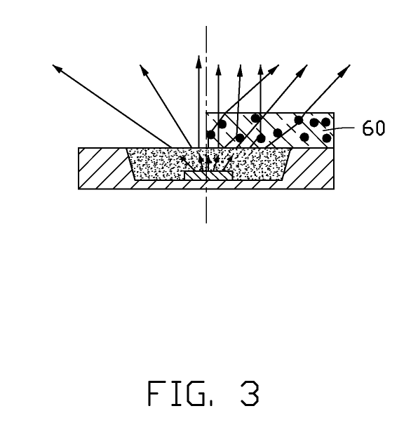

The light diffusion layer 60 is formed on the encapsulant 50. The light diffusion layer 60 includes a transparent layer 62 and a large amount of transparent particulates 70 uniformly distributed in the transparent layer 62. The transparent layer 62 may be made of transparent material such as epoxy, silicone or the like. The transparent particulates 70 may be made of high molecular material such as polyethylene, silicone, polymethyl methacrylate or the like. The transparent layer 62 has a refractive index larger or equal to that of the encapsulant 50, and the transparent particulates 70 have a refractive index less than that of the transparent layer 62. In this embodiment, the refractive index of the transparent particulates 70 ranges between 1.4 and 1.58. The transparent layer 62 has a height less than that of the encapsulant 50. The transparent layer 62 has a bottom face 601 directly contacting the top faces 21, 51 of the base 20 and the encapsulant 50. The transparent layer 62 has a lateral face 603 aligned with that of the base 20. A top face 602 of the transparent layer 62 is flat and parallel to the bottom face 601. The white light output from the encapsulant 50 enters the light diffusion layer 60 through an interface between the encapsulant 50 and the light diffusion layer 60. The white light is then refracted or reflected by the transparent particulates 70 within the transparent layer 62, thereby being uniformly scatted out of the light diffusion layer 60. FIG. 3 shows light pathways of the LED 10 with a right part covered by the light diffusion layer 60 and a left part uncovered by the light diffusion layer 60, wherein the right part of the LED 10 with the light diffusion layer 60 has more uniform light distribution than that of the left part of the LED 10 without the light diffusion layer 60.

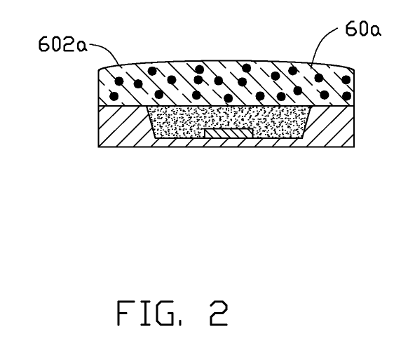

The top face 602 of the light diffusion layer 60 is flat in this embodiment. However, the shape of the light diffusion layer 60 may be changed according different requirements. For example, as shown in FIG. 2, a top face 602a of a light diffusion layer 60a may be a curved, convex face for converging light emitted from the chip 40, thereby producing a more concentrated light beam. The light diffusion layer 60a with the convex top face 602a has a thickness larger than that of the encapsulant 50.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

1. A light emitting diode (LED) comprising:
a base;
a chip mounted on the base;
an encapsulant covering the chip, the encapsulant having phosphors doped therein; and
a light diffusion layer comprising a transparent layer covering the encapsulant and a plurality of transparent particulates distributed within the transparent layer, the transparent particulates having a light refractive index less than that of the transparent layer, wherein the transparent layer has a light refractive index larger than that of the encapsulant.

2.-3. (canceled)

4. The LED of claim 1, wherein the transparent layer has a flat top face.

5. The LED of claim 4, wherein the transparent layer has a thickness less than that of the encapsulant.

6. The LED of claim 1, wherein the transparent layer has a curved, convex top face.

7. The LED of claim 6, wherein the transparent layer has a thickness larger than that of the encapsulant.

8. The LED of claim 1, wherein the base defines a cavity receiving the chip, the encapsulant being received in the cavity.

9. The LED of claim 8, wherein the encapsulant has a top face flush with that of the base.

10. The LED of claim 9, wherein the transparent layer directly contacts the top faces of the encapsulant and the base.

11. The LED of claim 1, wherein the transparent layer has a lateral face aligned with that of the base.

12. The LED of claim 1, wherein the transparent particulates are made of high molecular material.
